(19) United States
(12) Patent Application Publication
(10) Pub. No.: US 2025/0219032 A1
(43) Pub. Date: Jul. 3, 2025

(54) TECHNOLOGIES FOR BACK SIDE MICRO-LED ASSEMBLIES

(71) Applicants: Benjamin T. Duong, Phoenix, AZ (US); Sandeep Gaan, Chandler, AZ (US); Khaled Ahmed, San Jose, CA (US); Marcel M. Said, Beaverton, OR (US); Stephen Morein, San Jose, CA (US)

(72) Inventors: Benjamin T. Duong, Phoenix, AZ (US); Sandeep Gaan, Chandler, AZ (US); Khaled Ahmed, San Jose, CA (US); Marcel M. Said, Beaverton, OR (US); Stephen Morein, San Jose, CA (US)

(21) Appl. No.: 18/399,354

(22) Filed: Dec. 28, 2023

(51) Int. Cl. H01L 25/16; H01L 33/58; H01L 33/64

(52) U.S. Cl. CPC H01L 25/167; H01L 25/162; H10H 20/855; H10H 20/858

(57) ABSTRACT

Technologies for back side micro-LED assemblies are disclosed. In an illustrative embodiment, a micro-LED assembly includes several micro-LEDs and several photodiodes mounted on a base die. The base die is mounted on an integrated circuit (IC) die, such as a processor die. Through-silicon vias are defined in the IC die to carry electrical signals between the micro-LED assembly and transistors and other components near or at the front side of the IC die. An optical plug with an optical cable is positioned above the micro-LED assembly to couple light to and from the micro-LEDs and photodiodes. The short distance between the transistors on the front side of the IC die and the micro-LED assembly allows for high-bandwidth signals to be converted to optical signals with little loss. The optical cable can connect IC dies on the same circuit board, in the same housing, in the same rack, etc.

### BACKGROUND

As computing power increases, the bandwidth requirement likewise increases for communication over short distances, such as for communication between dies on the same circuit board or between circuit boards near each other. Copper traces and other electrical conductors are commonly used to carry high-bandwidth signals, but as frequencies increase, copper traces have more loss. In some cases, the loss for high-frequency signals can be significant even for dies adjacent to each other on the same circuit board.

### BRIEF DESCRIPTION OF THE DRAWINGS

FIG. 1 is an isometric view of a system with two integrated circuit components with micro-LED assemblies connected by an optical cable.

FIG. 2 is a cross-sectional view of one embodiment of one of the integrated circuit components of FIG. 1.

FIG. 3 is an isometric view of a system with an integrated circuit component with an integrated heat sink and a micro-LED assembly.

FIG. 4 is a cross-sectional view of the integrated circuit components of FIG. 3.

FIG. 5 is a cross-sectional view of one embodiment of one of the integrated circuit components of FIG. 1.

FIG. 6 is a cross-sectional view of one embodiment of one of the integrated circuit components of FIG. 1.

FIG. 7 is an isometric view of an integrated circuit component with two micro-LED assemblies connected by an optical cable.

FIG. 8 is a top view of a wafer and dies that may be included in a microelectronic assembly, in accordance with any of the embodiments disclosed herein.

FIG. 9 is a cross-sectional side view of an integrated circuit device that may be included in a microelectronic assembly, in accordance with any of the embodiments disclosed herein.

FIGS. 10A-10D are perspective views of example planar, gate-all-around, and stacked gate-all-around transistors.

FIG. 11 is a cross-sectional side view of an integrated circuit device assembly that may include a microelectronic assembly, in accordance with any of the embodiments disclosed herein.

FIG. 12 is a block diagram of an example electrical device that may include a microelectronic assembly, in accordance with any of the embodiments disclosed herein.

### DETAILED DESCRIPTION

In various embodiments disclosed herein, an integrated circuit component includes a semiconductor die with a micro-light-emitting diode (micro-LED) assembly mounted on the back side of the semiconductor die. The micro-LED assembly can be connected to circuitry on the front side of the semiconductor die using through-silicon vias. The micro-LED assembly may include micro-LEDs and/or photodetectors to send and/or receive optical data. An optical cable is coupled to the micro-LED assembly to transport the optical signal to another component. The short distance from the circuitry on the front side of the semiconductor die to the micro-LED assembly on the back side of the semiconductor die can carry a relatively high-frequency signal with relatively low loss. Other configurations are disclosed as well, such as a micro-LED assembly mounted on an integrated heat spreader of an integrated circuit component.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

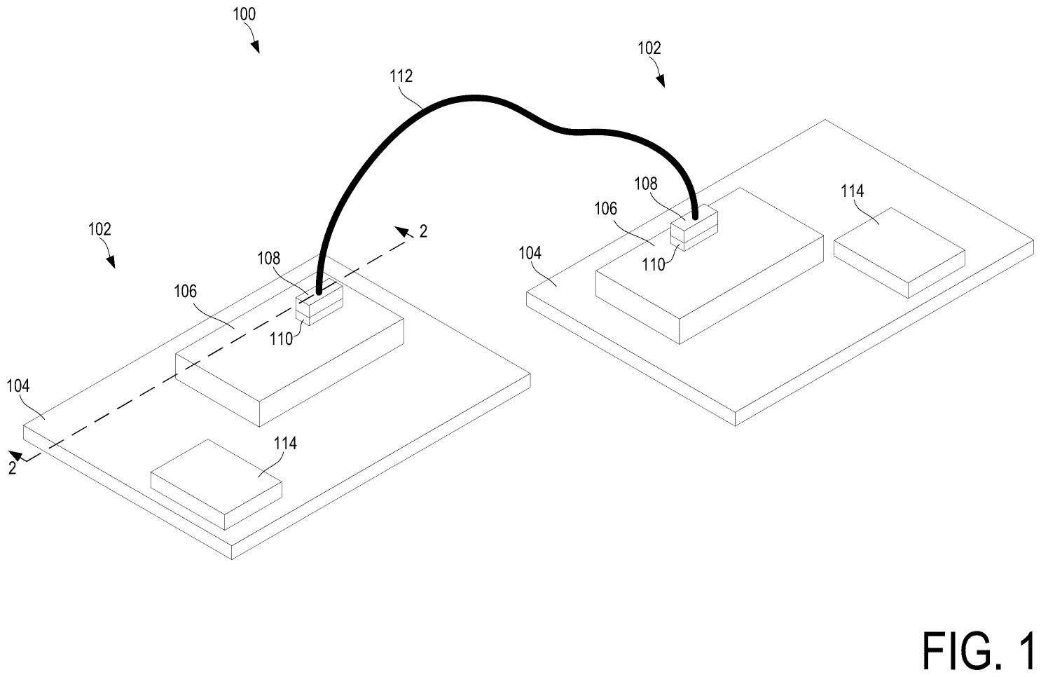

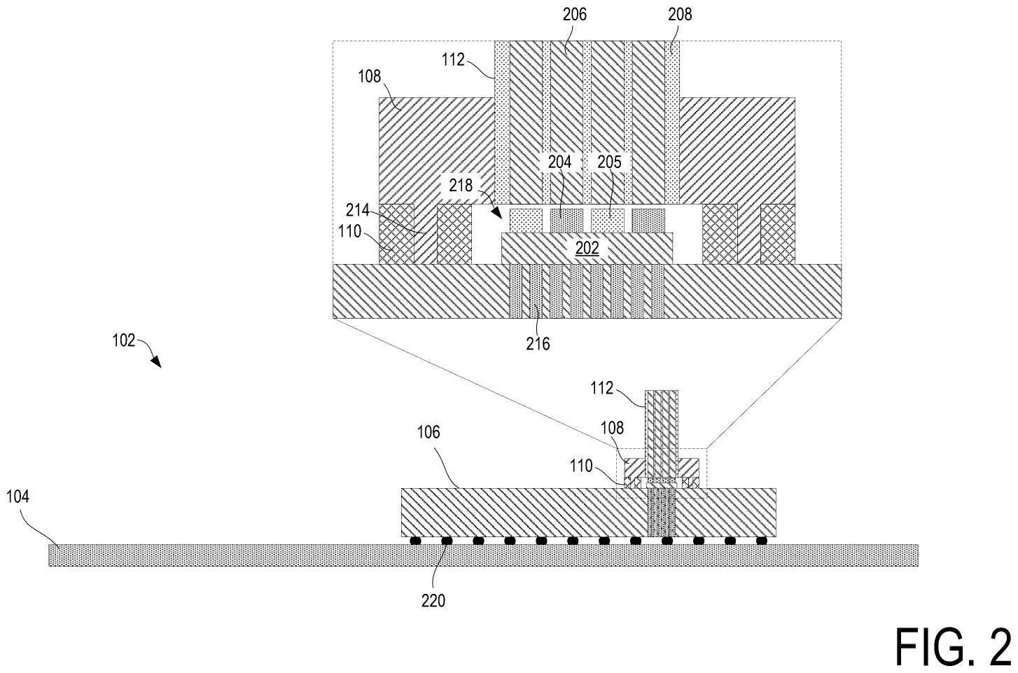

Referring now to FIGS. 1 and 2, in one embodiment, a system 100 includes two integrated circuit components 102. Each integrated circuit component 102 includes a circuit board 104 and an integrated circuit (IC) die 106. The integrated circuit components 102 are connected by an optical cable 112. FIG. 1 shows a perspective view of an integrated circuit component 102, and FIG. 2 shows a cross-sectional view of one embodiment of the integrated circuit component 102.

In an illustrative embodiment, a micro-LED assembly 218 is mounted on the back side of the IC die 106 (see FIG. 2). Circuitry, such as transistors, capacitors, resistors, etc., are on the front side of the die 106, facing the circuit board 104. The micro-LED assembly 218 mounted on the back side IC die 106 is connected to the front side of the IC die 106 by through-silicon vias 216. In an illustrative embodiment, the micro-LED assembly 218 includes a base die 202, one or more micro-LEDs 204, and one or more photodetectors 205. Optical fiber cores 206 of the optical cable 112 are aligned with the micro-LED dies 204 and/or the photodetector dies 205. The optical fiber cores 206 are surrounded by a cladding material 208. The optical cable 112 is attached to a plug 108, which is mated with a receptacle 110 mounted on the die 106. In the illustrative embodiment, the optical cable 112 includes a single multi-core fiber. Additionally or alternatively, the optical cable 112 may include several single-core fibers and/or several multi-core fibers, all of which may terminate at the plug 108.

In use, the micro-LED assembly 218 is connected to transistors, micro-LED driver circuitry, photodetector driver circuitry, etc., on the front side of the IC die 106 through the through-silicon vias 216. High-speed input/output (HSIO) data signals can be sent from the circuitry on the front side of the IC die 106 to and from the micro-LED assembly 218 with relatively high frequency and relatively low loss, such as sending signals at a frequency up to 1-32 gigahertz with a loss of less than 0.1-10 dB. In an illustrative embodiment, signals are sent to and received from the micro-LED assembly 218 at a frequency up to about 32 gigahertz with a loss of less than 3 dB. Electrical signals sent from the circuitry on the front side of the IC die 106 are converted by a micro-LED die 204 to an optical signal, which is coupled to the optical fiber core 206 in the optical cable 112. The optical signal is transported to another component, such as to the micro-LED assembly 218 on the other integrated circuit component 102. The optical signal is converted to an electrical signal at a photodetector die 205, and the electrical signal is sent to the circuitry on the front side of the IC die 106. In this manner, HSIO signals can be sent between the IC dies 106 with relatively low loss. The integrated circuit components 102 may be any suitable distance apart, such as 0.05-1,000 meters. The integrated circuit components 102 may be in the same housing, in the same rack, in the same data center, etc. In some embodiments, as described in more detail below, the optical cable 112 can connect micro-LED assemblies 218 on two different dies 106 on the same circuit board 104.

The illustrative circuit board 104 may be made from ceramic, glass, and/or organic-based materials with fiberglass and resin, such as FR-4. The circuit board 104 may have any suitable length or width, such as 10-500 millimeters. The circuit board 104 may have any suitable thickness, such as 0.2-5 millimeters. The circuit board 104 may support additional components besides the components shown in FIG. 1 or 2, such as additional photonic or electronic integrated circuit components, a memory device, additional circuit components, etc.

The circuit board 104 may have an organic or inorganic core, such as an organic core of resin and fiberglass or an inorganic core, such as a glass core. A glass core may be made of any suitable material that may be crystalline, non-crystalline, amorphous, etc., such as fused silicon, borosilicate, sapphire, yttrium aluminum garnet, etc. The glass core may be, e.g., aluminosilicate glass, borosilicate glass, alumino-borosilicate glass, silica, fused silica. The glass core may include one or more additives, such as Al2O3, B2O3, MgO, CaO, SrO, BaO, SnO2, Na2O, K2O, SrO, P2O3, ZrO2, Li2O, Ti, and Zn. The glass core may comprise silicon and oxygen, as well as any one or more of aluminum, boron, magnesium, calcium, barium, tin, sodium, potassium, strontium, phosphorus, zirconium, lithium, titanium, and zinc. The glass core may include at least 20-40 percent silicon by weight, at least 20-40 percent oxygen by weight, and at least 5 percent aluminum by weight. For example, some embodiments of the glass core may include, e.g., at least 20-23 percent silicon and at least 20-26 percent oxygen by weight.

The one or more IC dies 106 may include any suitable electronic integrated circuit component, such as resistors, capacitors, inductors, transistors, etc. The one or more IC dies 106 may include any suitable analog and/or digital circuitry, such as a processor, a memory, an application-specific integrated circuit (ASIC), a field-programmable gate array (FPGA), a router, a modem, communication circuitry, a motherboard, a daughterboard, a mezzanine board, an auxiliary board, etc. The IC dies 106 may have any suitable length or width, such as 1-300 millimeters. The IC dies 106 may have any suitable thickness, such as 0.05-5 millimeters. The through-silicon vias 216 may extend through any suitable height, such as through the entire IC die 106. The through-silicon vias 216 may be filled with any suitable conductive material, such as copper, tungsten, conductive polymers, polysilicon, and/or the like. In some embodiments, the through-silicon vias 216 may extend from, e.g., the back side of the IC die 106 to transistors on the front end-of-line (FEOL) portion of the front side of the IC die 106.

The integrated circuit component 102 may include other components, such as additional IC dies 114, components such as capacitors, inductors, voltage regulators, etc. In an illustrative embodiment, the IC die 106 is connected to the circuit board 104 with solder balls 220.

In an illustrative embodiment, the micro-LED assembly 218 includes a base die 202, one or more micro-LED dies 204, and one or more photodetector dies 205. The base die 202 may be a silicon semiconductor die. In other embodiments, the base die 202 may be another type of die, such as glass, a III-V semiconductor die composing, e.g., boron, aluminum, gallium, indium, nitrogen, phosphorus, arsenic, tin, etc. The base die 202 may include one or more through-silicon (or through-substrate) vias, traces, pads, etc. The base die 202 may include one or more layers of traces. In an illustrative embodiment, driver circuitry for the micro-LED dies 204 and/or the photodetector dies 205 are on the front side of the IC die 106. In some embodiments, the base die 202 may include driver circuitry for the micro-LED dies 204 and/or the photodetector dies 205.

The micro-LEDs 204 may be any suitable micro-LED, such as gallium nitride micro-LEDs 204, quantum dot LEDs, single nanowire LED, etc. As used herein, a micro-LED refers to a light-emitting diode with a length and width of a light-emitting surface of less than 100 micrometers. In some embodiments, the length and/or width of a light-emitting surface of the micro-LEDs 204 may be smaller, such as less than 10-50 micrometers. In the illustrative embodiment, the micro-LEDs 204 are created on a separate substrate and transferred to the base die 202, the IC die 106, or other dies.

The micro-LED 204 may have any suitable wavelength, such as 380-1,500 nanometers, depending on the particular material and structure of the micro-LED 204. In the illustrative embodiment, the micro-LED 204 may be between, e.g., 400-450 nanometers. The micro-LED 204 may have any suitable bandwidth, such as 1-15 nanometers.

In one embodiment, the photodiodes 205 may be similar to or the same as the micro-LEDs 204, with an opposite bias to detect light rather than create it. The photodiodes 205 may be made from any suitable materials, such as silicon, silicon-germanium (SiGe), a III-V material including those listed above for the micro-LEDs 204, etc. In some embodiments, the photodiodes 205 may be microphotodiodes 205. As used herein, a microphotodiode 205 refers to a photodiode with a length and width of a light-sensitive surface of less than 100 micrometers. In some embodiments, the length and/or width of a light-sensitive surface of the microphotodiodes 205 may be smaller, such as less than 10-50 micrometers. Similar to the micro-LEDs 204, the photodiodes 205 may be created on a separate substrate and transferred to the base die 202. In some embodiments, the photodiodes 205 may be able to be used as micro-LEDs 204 and/or the micro-LEDs 204 may be able to be used as photodiodes 205. In the illustrative embodiment, each micro-LED 204 and microphotodiode 205 interfaces with the die 202 on which they are mounted through a copper pad on the die 202 and a transparent electrode on top of the micro-LED 204 or microphotodiode 205. The transparent electrode may be any suitable transparent conductive material, such as indium tin oxide (ITO). The micro-LEDs 204 and/or photodiodes 205 may be secured to the base die 202 in any suitable manner, such as by using solder, hybrid bonding, etc.

In the illustrative embodiment, the photodiodes 205 are spaced apart from other photodiodes 205 and/or from micro-LEDs 204 in order to prevent cross-talk. The photodiodes 205 and/or micro-LEDs 204 may be spaced apart by, e.g., 10-500 micrometers, as measured from the center of one photodiode 205 and/or micro-LED 204 to the next. In some embodiments, the photodiodes 205 may be responsive to a similar wavelength range as a corresponding micro-LED 204, and different micro-LEDs 204 may have different wavelength ranges.

In the illustrative embodiment, each micro-LED 204 has a corresponding photodiode 205 next to it on the same die 202, creating a transmit/receive pair. In other embodiments, a die 202 may have more receive channels or more transmit channels. Each micro-LED 204 and photodiode 205 is connected to a drive and receive circuit, respectively, that interfaces with other electronic components of the base die 202 and/or IC die 106. The micro-LED assembly 218 may include any suitable number of micro-LEDs 204 and/or photodiodes 205, such as 1-10,000. Each micro-LED 204 may transmit, and each photodiode 205 may receive data at a rate of, e.g., 1-128 gigabits per second. In the illustrative embodiment, the IC die 106 sends data by modulating the micro-LED 204 at different amplitudes, such as on and off. Any suitable encoding may be used, such as return-to-zero encoding, non-return-to-zero encoding, amplitude shift keying, multilevel amplitude shift keying, pulse amplitude modulation, phase shift keying, quadrature amplitude modulation, etc. In the illustrative embodiment, data can be transferred by a micro-LED 204 to a photodiode 205 with an energy efficiency of less than 0.5 picojoules per bit over a range of up to, e.g., 1-50 meters. In other embodiments, data can be transferred by a micro-LED 204 to a photodiode 205 with an energy efficiency of, e.g., less than 0.5-5 picojoules per bit.

In one embodiment, each micro-LED assembly 218 includes the micro-LEDs 204 and photodiodes 205 in a linear array, as shown in FIG. 2. In other embodiments, each micro-LED assembly 218 may array the micro-LEDs 204 and photodiodes 205 in a two-dimensional array, such as an array with a length and/or width of 1-1,000 micro-LEDs 204 or photodiodes 205. In some embodiments, the micro-LEDs 204 and photodiodes 205 may be alternating, as shown in the figures. In other embodiments, micro-LEDs 204 may be grouped together (e.g., in a line or a two-dimensional array) and photodiodes 205 may be grouped together (e.g., in a line or a two-dimensional array).

The optical cable 112 may include any suitable number of optical fiber cores 206, such as 1-10,000. In an illustrative embodiment, the optical cable 112 includes an optical fiber core 206 for each micro-LED 204 and photodiode 205. The optical fiber cores 206 may be any suitable material that is transparent to the wavelength used, such as glass, fused silica, plastic, etc. In an illustrative embodiment, the optical fiber cores 206 are multi-mode fibers with a core diameter of, e.g., 50-100 micrometers. In other embodiments, the optical fiber cores 206 may be single- or few-mode fibers with a core diameter of, e.g., 1-10 micrometers. In some embodiments, the optical fiber cores 206 may be part of polarization-maintaining optical fibers. The cladding 208 may be any suitable material with a lower index of refraction than the core 206, such as glass, fused silica, or plastic. The optical fiber cores 206 may have a different doping than the cladding 208 in order to change the difference in index of refraction between the core 206 and the cladding 208. The optical cable 112 may have any suitable length, such as 0.1-1,000 meters. In some embodiments, a microlens array (or pair of micro lens arrays) may be positioned between the micro-LEDs 204/photodiodes 205 and the optical fiber cores 206 in order to increase coupling to and from the optical fiber cores 206.

The optical cable 112 terminates at an optical plug 108. The optical plug 108 includes a housing that holds the end of the optical cable 112 in place. The housing of the optical plug 108 may be any suitable material, such as plastic, ceramic, metal, glass, a combination thereof, etc. The optical plug 108 mates with an optical receptacle 110 mounted on the surface of the die 106. The optical receptacle 110 may be made of any suitable material, such as plastic, ceramic, metal, glass, a combination thereof, etc. In an illustrative embodiment, an alignment feature 214 extends from the optical plug 108 and mates with a corresponding alignment feature defined in the optical receptacle 110. The optical receptacle 110 may be attached to the die 106 in any suitable manner, such as by using die bonding films, epoxy adhesives, bump bonding, hybrid bonding, etc. The optical plug 108 and/or the optical receptacle 110 may include additional components for aligning and/or retaining the optical plug 108, such as alignment grooves, clips, tabs, etc. In use, the optical plug 108 can be removably plugged into the optical receptacle 110. In doing so, the optical cable 112 is positioned to couple light from the micro-LEDs 204 to the optical fiber cores 206 and/or light from the optical fiber cores 206 into the photodiodes 205. The optical plug 108 can be plugged and unplugged into various components as necessary as a system is set up, taken apart, reconfigured, etc.

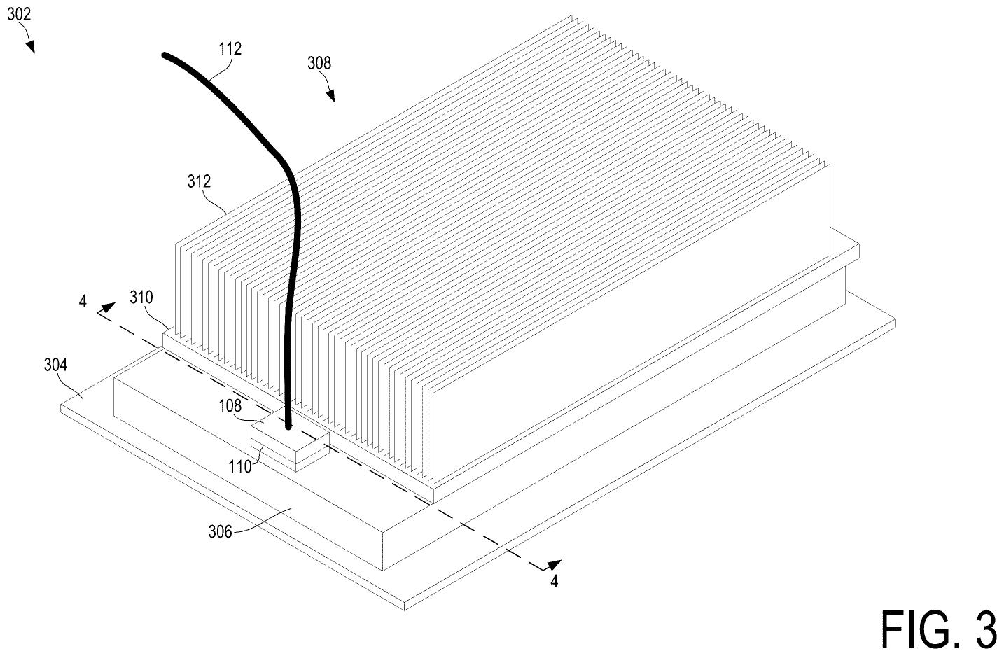

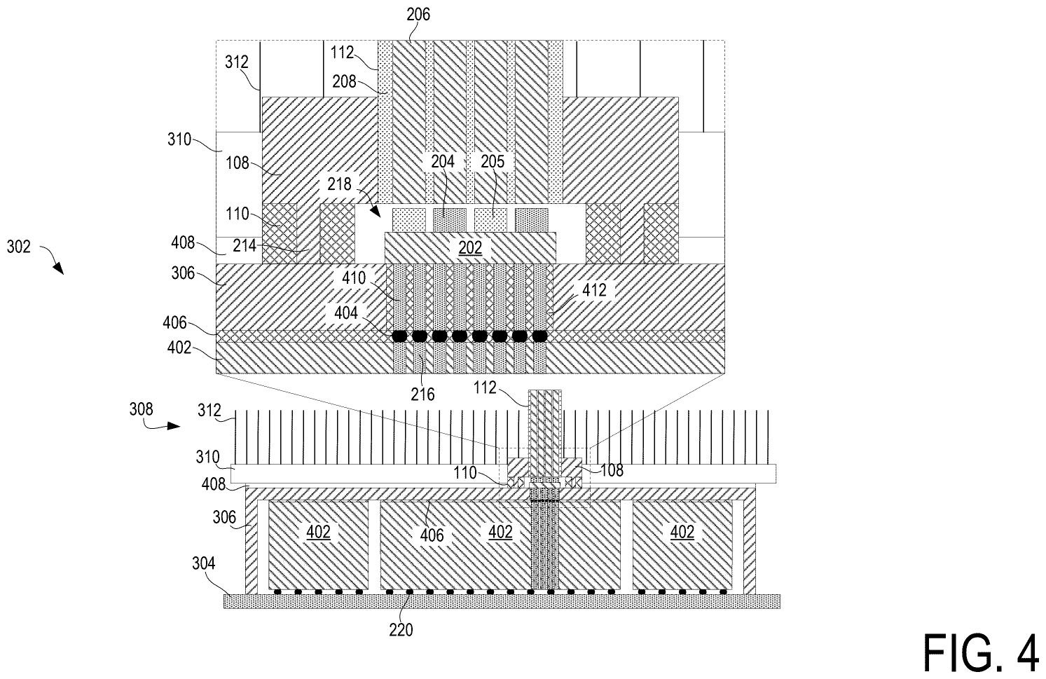

Referring now to FIGS. 3 and 4, in one embodiment, an integrated circuit component 302 includes a circuit board 304, one or more IC dies 402 mounted on the circuit board 304, and an integrated heat spreader (IHS) 306. A micro-LED assembly 218 is mounted on the IHS 306. The micro-LED assembly 218 is connected to through-silicon vias 216 in one of the IC dies 402 using through-IHS vias 410 and solder balls 404.

The various components of the integrated circuit component 302 may be similar to or the same as the corresponding component of the integrated circuit component 102, a description of which will not be repeated in the interest of clarity. For example, the circuit board 304 may be similar to the circuit board 104, the IC die 402 may be similar to the IC die 106, etc.

In the illustrative embodiment, each through-silicon via 216 is connected to a corresponding through-IHS via 410. The through-IHS vias 410 may be made of any suitable material, such as copper, aluminum, tungsten, polysilicon, etc. The through-IHS vias 410 may be surrounded by a dielectric 412 to isolate the through-IHS vias 410 from each other and from the IHS 306, which may be conductive. The dielectric 412 may be any suitable dielectric, such as silicon dioxide, silicon nitride, intrinsic silicon, epoxy, mold, Ajimoto build-up film (ABF), etc. In the illustrative embodiment, the micro-LED assembly 218 is positioned on a region of the IHS 306 that is not covered by the heat sink 308, as shown in the figure. In some embodiments, the micro-LED assembly 218 may be partially or fully surrounded by the heat sink 308.

The IHS 306 may be made of any suitable material with a high thermal conductivity, such as copper, aluminum, other metals, metal alloys, coated metals, combinations of metals, etc. In some embodiments, a heat sink 308 may be mounted on the IHS 306. The illustrative heat sink 308 has a heat sink base 310 and several heat sink fins 312. The fins 312 may be any suitable structure that has a high surface area-to-volume ratio. The fins 312 may be any suitable shape, such as a plane, a rod, a folded sheet, etc. In the illustrative embodiment, the heat sink fins 312 are bonded to the heat sink base 310 by solder, glue, or other adhesive. In other embodiments, the heat sink fins 312 may be removably fastened to the heat sink base 310. In some embodiments, the heat sink 308 may be a unitary piece that includes both the heat sink base 310 and the heat sink fins 312. In some embodiments, the heat sink baes 310 and fins 312 may be part of a socket. More generally, the heat sink 308 may be manufactured in any suitable manner, such as extrusion, skiving, stamping, forging, machining, 3D printing, etc. In some embodiments, some or all of the receptacle may be part of the IHS 306.

One purpose of the heat sink 308 is to absorb heat from the integrated circuit component 302 and transfer the heat to air. In some embodiments, a fan (not shown in FIGS. 3 and 4) may blow air onto and/or through the heat sink fins 312.

The heat sink 308 may be made from any suitable material. In the illustrative embodiment, the heat sink base 310 and the heat sink fins 312 are made from a high-thermal-conductivity material, such as copper, aluminum, or another material with a thermal conductivity greater than 100 W/(m×K). In some embodiments, the heat sink base 310 and the heat sink fins 312 may be made of different material. For example, the heat sink base 310 may be aluminum, and the heat sink fins 312 may be copper. In some embodiments, the heat sink base 310 may have more than one layer of different materials.

The heat sink 308 may have any suitable shape or dimensions. For example, the heat sink 308 may have a width of 10-250 millimeters, a length of 10-250 millimeters, and/or a height of 10-100 millimeters. The thickness of the base plate 310 may be any suitable thickness, such as 1-10 millimeters. The height of the fins 312 may be any suitable height, such as 5-100 millimeters. In some embodiments, the heat sink 308 may be a cold plate used in a liquid cooling system or liquid immersion system and may not have any external fins 312.

The illustrative heat sink 308 is a rectangular shape. In other embodiments, the heat sink 308 may be any suitable shape, such as a square, a circle, etc. The illustrative heat sink base 310 has a flat surface on the bottom. In the illustrative embodiment, the central region of the bottom of the heat sink base 310 contacts the flat surface of the IHS 306. Heat flows from the central region of the heat sink base 310 to the edges of the heat sink base 310 and into the fins 312. In some embodiments, the heat sink base 310 does not have a flat surface on the bottom. For example, the heat sink base 310 may have a pedestal extruding from the bottom of the heat sink base 310 that contacts some or all of the IHS 306. In some embodiments, the heat sink 308 may include other heat-transferring components such as one or more heat pipes, a thermoelectric heater/cooler, etc.

A thermal interface material (TIM) 406 is between the IC dies 402 and the IHS 306. Another TIM 408 may be between the IHS 306 and the heat sink 308. The TIMs 406, 408 may be any suitable material, such as a silver thermal compound or polymer.

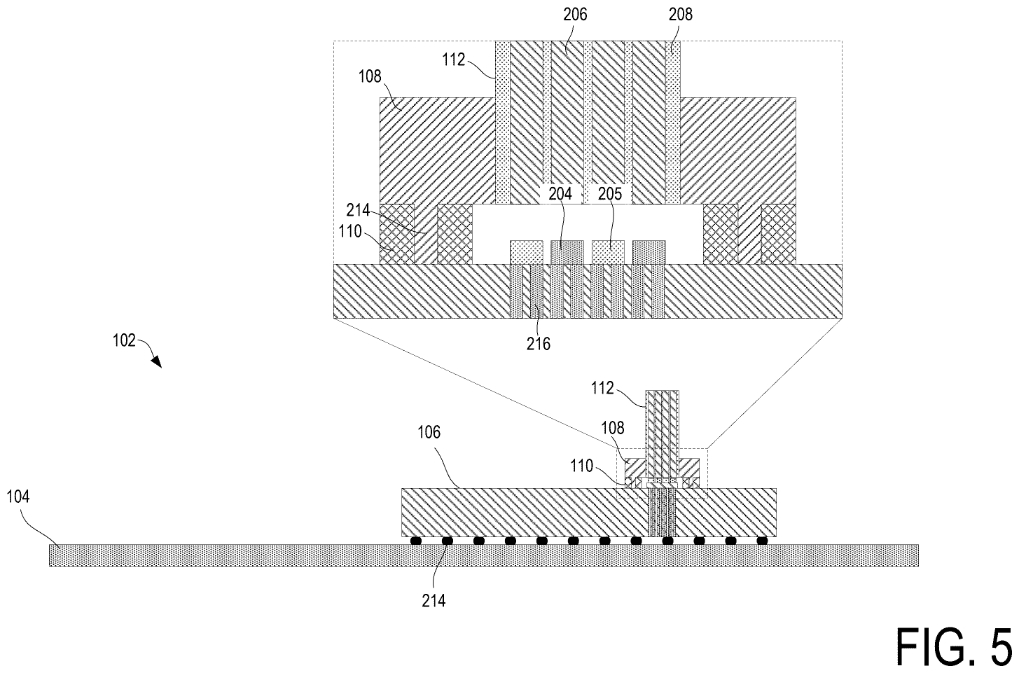

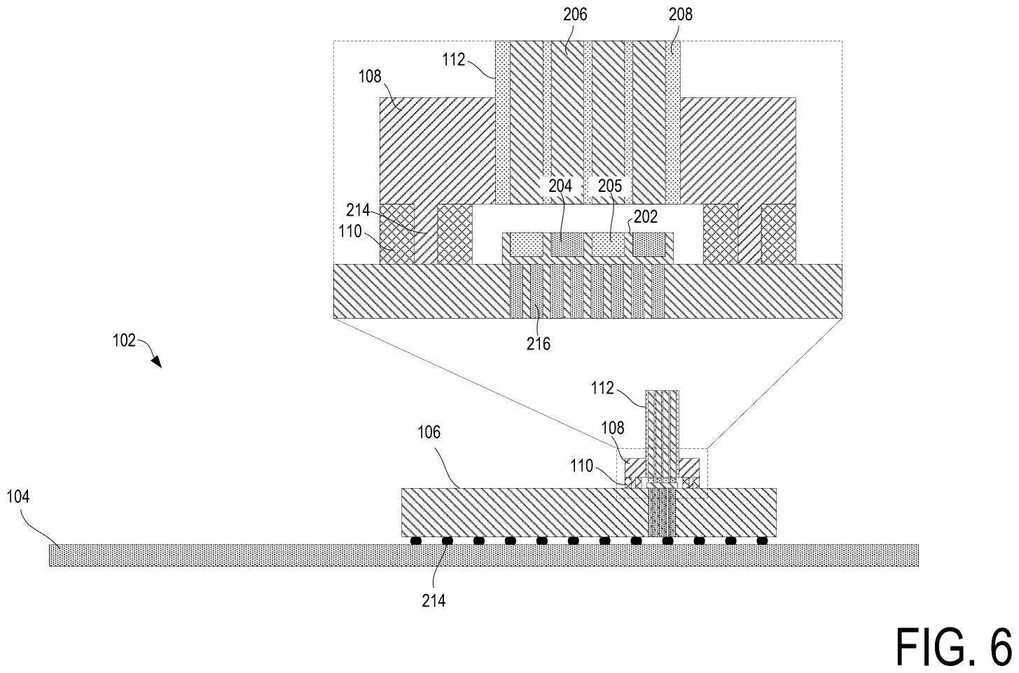

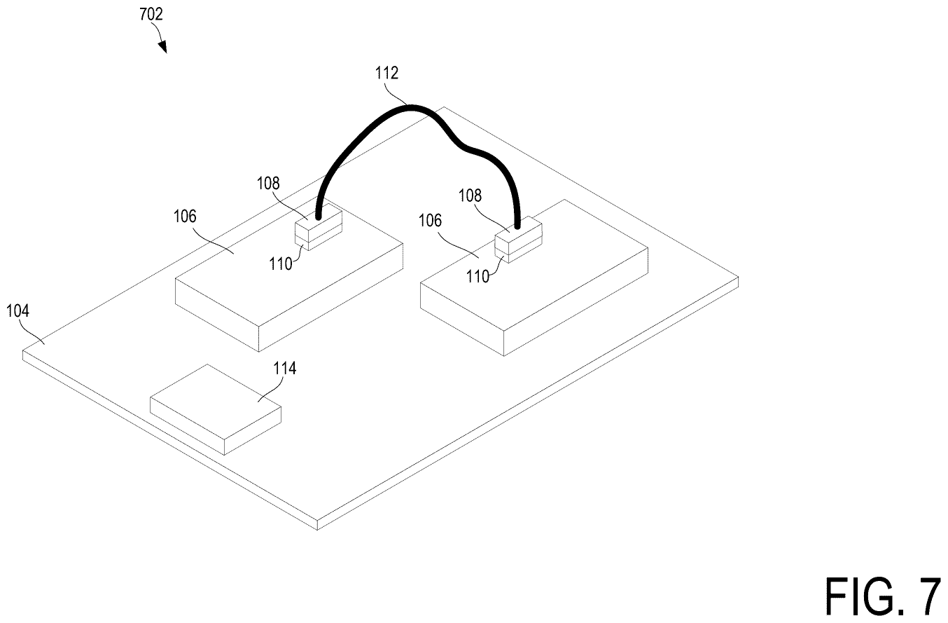

It should be appreciated that the embodiments described above are some but not all of the envisioned embodiments, and other embodiments are envisioned as well. For example, in one embodiment, the micro-LEDs 204 and/or the photodiodes 205 may be mounted directly on the IC die 106, without the base die 202, as shown in FIG. 5. In another embodiment, several micro-LEDs 204 and/or photodiodes 205 may be fabricated on a base die 202, as shown in FIG. 6. In another embodiment, an integrated circuit component 702 may include two IC dies 106, each with a micro-LED assembly 218, that are mounted on the same circuit board 104, as shown in FIG. 7. The two IC dies 106 can be connected by an optical cable 112, which can enable optical connectivity between the dies 106 over short distances, such as a few centimeters.

It should be appreciated that different variations of the examples shown above have different features that can be used together in any suitable combination. For example, the micro-LEDs 204 and/or the photodiodes 205 may be mounted directly on the IHS 306, without the base die 202.

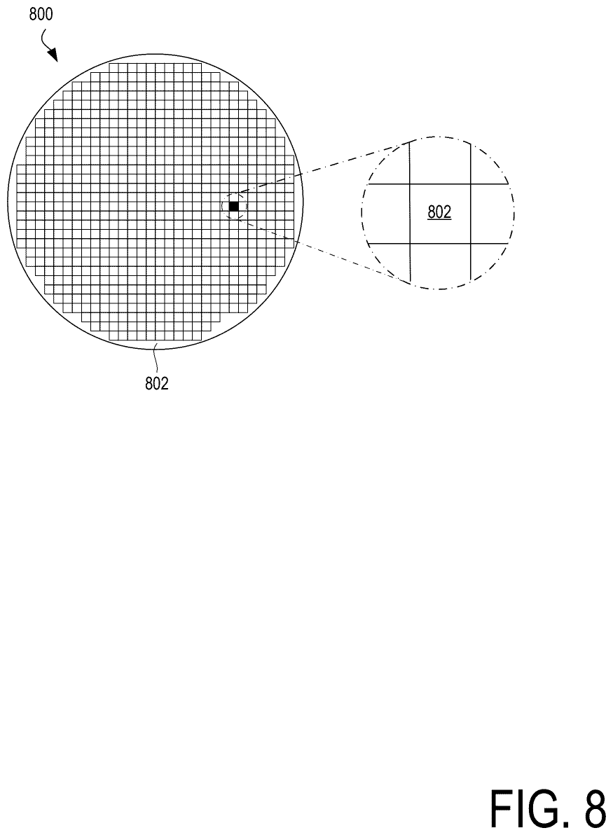

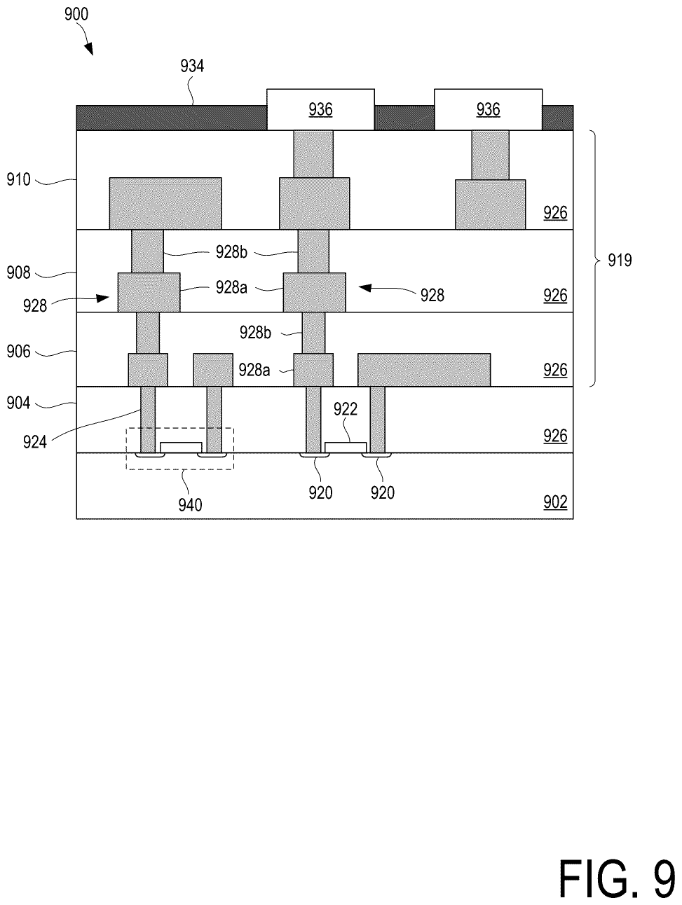

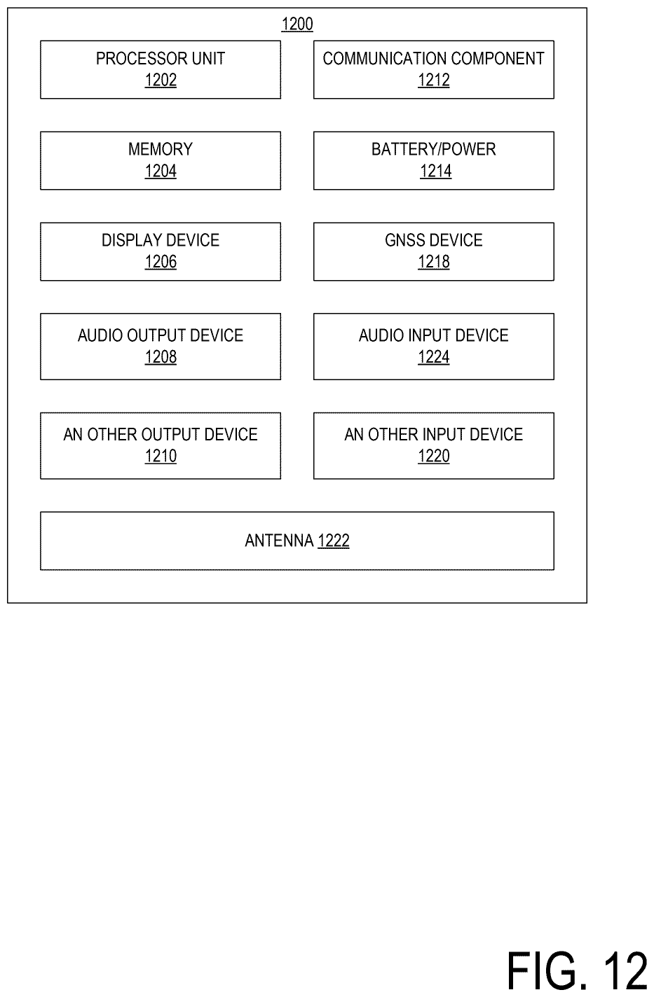

FIG. 8 is a top view of a wafer 800 and dies 802 that may be included in any of the integrated circuit components 102, 302, 702 disclosed herein (e.g., as any suitable ones of the dies 106, 402, 114, 204, 205). The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may be any of the dies 106, 402, 114, 204, 205 disclosed herein. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1202 of FIG. 12) or other logic that is configured to store information in the memory devices or execute instructions stored in the memory array. Various ones of the integrated circuit components 102, 302, 702 disclosed herein may be manufactured using a die-to-wafer assembly technique in which some dies 106, 402, 114, 204, 205 are attached to a wafer 800 that include others of the dies 106, 402, 114, 204, 205 and the wafer 800 is subsequently singulated.

FIG. 9 is a cross-sectional side view of an integrated circuit device 900 that may be included in any of the integrated circuit components 102, 302, 702 disclosed herein (e.g., in any of the dies 106, 402, 114, 204, 205). One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

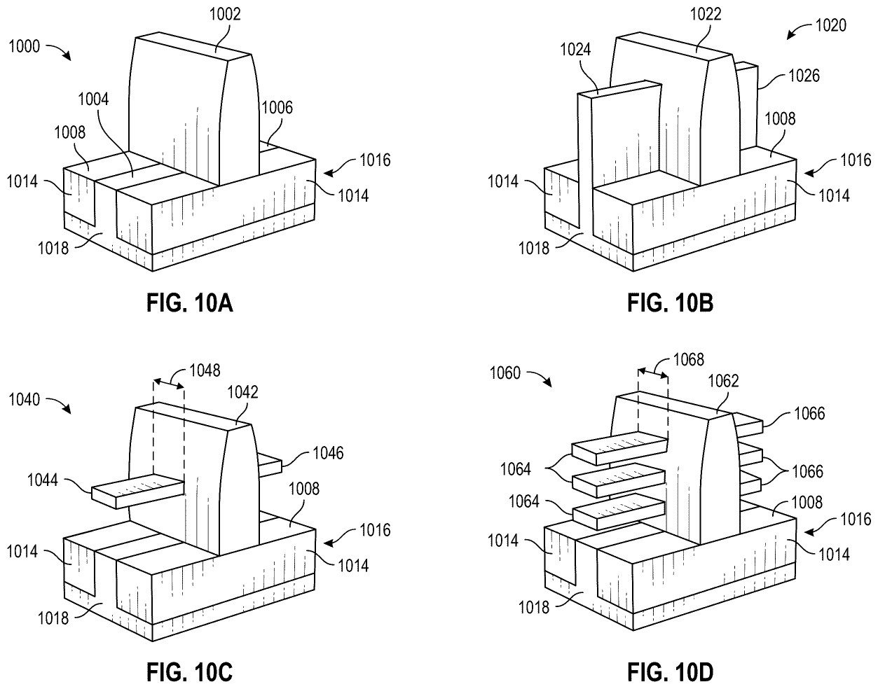

FIGS. 10A-10D are simplified perspective views of example planar, FinFET, gate-all-around, and stacked gate-all-around transistors. The transistors illustrated in FIGS. 10A-10D are formed on a substrate 1016 having a surface 1008. Isolation regions 1014 separate the source and drain regions of the transistors from other transistors and from a bulk region 1018 of the substrate 1016.

FIG. 10A is a perspective view of an example planar transistor 1000 comprising a gate 1002 that controls current flow between a source region 1004 and a drain region 1006. The transistor 1000 is planar in that the source region 1004 and the drain region 1006 are planar with respect to the substrate surface 1008.

FIG. 10B is a perspective view of an example FinFET transistor 1020 comprising a gate 1022 that controls current flow between a source region 1024 and a drain region 1026. The transistor 1020 is non-planar in that the source region 1024 and the drain region 1026 comprise “fins” that extend upwards from the substrate surface 1028. As the gate 1022 encompasses three sides of the semiconductor fin that extends from the source region 1024 to the drain region 1026, the transistor 1020 can be considered a tri-gate transistor. FIG. 10B illustrates one S/D fin extending through the gate 1022, but multiple S/D fins can extend through the gate of a FinFET transistor.

FIG. 10C is a perspective view of a gate-all-around (GAA) transistor 1040 comprising a gate 1042 that controls current flow between a source region 1044 and a drain region 1046. The transistor 1040 is non-planar in that the source region 1044 and the drain region 1046 are elevated from the substrate surface 1028.

FIG. 10D is a perspective view of a GAA transistor 1060 comprising a gate 1062 that controls current flow between multiple elevated source regions 1064 and multiple elevated drain regions 1066. The transistor 1060 is a stacked GAA transistor as the gate controls the flow of current between multiple elevated S/D regions stacked on top of each other. The transistors 1040 and 1060 are considered gate-all-around transistors as the gates encompass all sides of the semiconductor portions that extends from the source regions to the drain regions. The transistors 1040 and 1060 can alternatively be referred to as nanowire, nanosheet, or nanoribbon transistors depending on the width (e.g., widths 1048 and 1068 of transistors 1040 and 1060, respectively) of the semiconductor portions extending through the gate.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

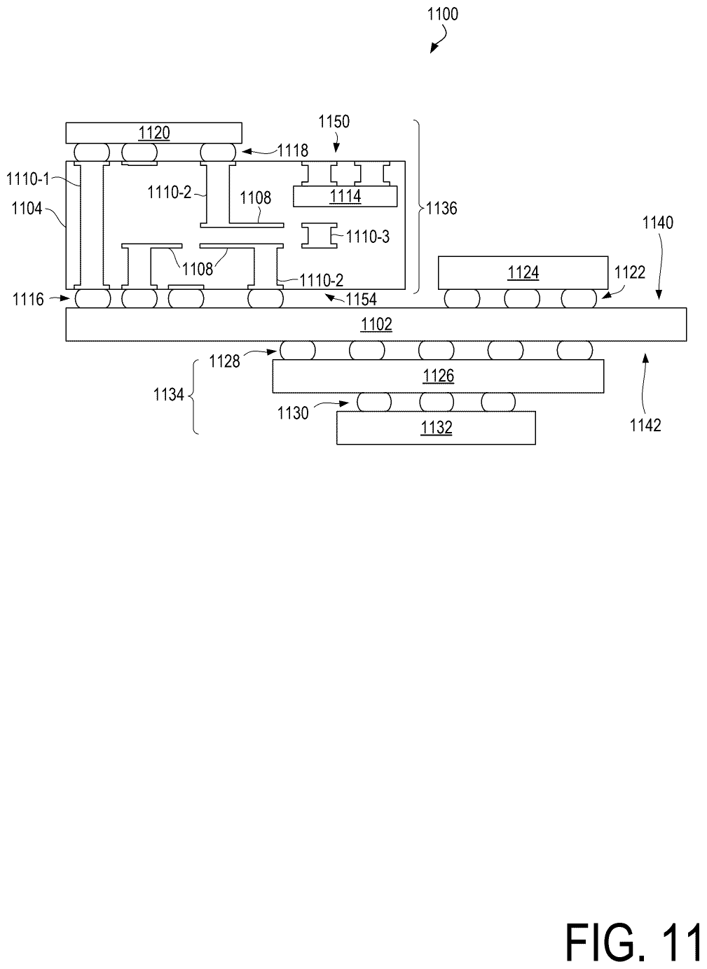

FIG. 11 is a cross-sectional side view of an integrated circuit device assembly 1100 that may include any of the integrated circuit components 102, 302, 702 disclosed herein. In some embodiments, the integrated circuit device assembly 1100 may be an integrated circuit components 102, 302, 702. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142. Any of the integrated circuit components discussed below with reference to the integrated circuit device assembly 1100 may take the form of any suitable ones of the embodiments of the integrated circuit components 102, 302, 702 disclosed herein.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. In some embodiments the circuit board 1102 may be, for example, the circuit board 104, 304. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpacked integrated circuit product that includes one or more integrated circuit dies (e.g., the die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the integrated circuit components 102, 302, 702 disclosed herein. For example, any suitable ones of the components of the electrical device 1200 may include one or more of the integrated circuit device assemblies 1100, integrated circuit components 1120, integrated circuit devices 900, or integrated circuit dies 802 disclosed herein, and may be arranged in any of the integrated circuit components 102, 302, 702 disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such as speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include an other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include an other input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising an integrated circuit die; and a micro-light-emitting diode (micro-LED) assembly comprising one or more micro-LEDs; wherein the micro-LED assembly is mounted on the integrated circuit die.

Example 2 includes the subject matter of Example 1, and further including an optical receptacle mounted on the integrated circuit die, wherein the optical receptacle is to align an optical plug to couple light from the micro-LED assembly.

Example 3 includes the subject matter of any of Examples 1 and 2, and further including the optical plug, wherein the optical plug is mated with the optical receptacle; and one or more optical fiber cores, wherein the one or more optical fiber cores terminate at the optical plug, wherein individual optical fiber cores of the one or more optical fiber cores are aligned to a corresponding micro-LED of the micro-LED assembly.

Example 4 includes the subject matter of any of Examples 1-3, and further including one or more microlenses to couple light between the one or more micro-LEDs and the one or more optical fiber cores.

Example 5 includes the subject matter of any of Examples 1-4, and wherein the one or more micro-LEDs comprise gallium and nitrogen.

Example 6 includes the subject matter of any of Examples 1-5, and wherein the micro-LED assembly further comprises one or more photodiodes.

Example 7 includes the subject matter of any of Examples 1-6, and further including a second integrated circuit die different from the integrated circuit die; a second micro-LED assembly, wherein the second micro-LED assembly comprises one or more micro-LEDs and one or more photodiodes, wherein the second micro-LED assembly is mounted on the second integrated circuit die; and an optical cable that optically couples the micro-LED assembly and the second micro-LED assembly.

Example 8 includes the subject matter of any of Examples 1-7, and further including a circuit board, wherein the integrated circuit die is mounted on the circuit board, wherein the second integrated circuit die is mounted on the circuit board.

Example 9 includes the subject matter of any of Examples 1-8, and further including a first circuit board and a second circuit board different from the first circuit board, wherein the integrated circuit die is mounted on the first circuit board, wherein the second integrated circuit die is mounted on the second circuit board.

Example 10 includes the subject matter of any of Examples 1-9, and wherein a plurality of transistors are defined at a front end-of-line (FEOL) portion of the integrated circuit die, wherein the micro-LED assembly is mounted on a back side of the integrated circuit die, wherein a plurality of through-silicon vias are defined in the integrated circuit die, wherein the plurality of through-silicon vias connect the plurality of transistors to the micro-LED assembly.

Example 11 includes the subject matter of any of Examples 1-10, and wherein the plurality of transistors are to modulate an amplitude of the one or more micro-LEDs using the plurality of through-silicon vias as a rate of at least one gigahertz.

Example 12 includes the subject matter of any of Examples 1-11, and wherein the plurality of transistors are to modulate an amplitude of the one or more micro-LEDs using the plurality of through-silicon vias as a rate of at least five gigahertz.

Example 13 includes an apparatus comprising a substrate; one or more integrated circuit dies mounted on the substrate; an integrated heat spreader (IHS) mounted on the substrate, the IHS thermally coupled to the one or more integrated circuit dies; and a light-emitting diode (LED) assembly comprising a plurality of LEDs; wherein the LED assembly is mounted on the IHS.

Example 14 includes the subject matter of Example 13, and further including an optical receptacle mounted on the IHS, wherein the optical receptacle is to align an optical plug to couple light from the LED assembly.

Example 15 includes the subject matter of any of Examples 13 and 14, and further including the optical plug, wherein the optical plug is mated with the optical receptacle; and one or more optical fiber cores, wherein the one or more optical fiber cores terminate at the optical plug, wherein individual optical fiber cores of the one or more optical fiber cores are aligned to a corresponding LED of the LED assembly.

Example 16 includes the subject matter of any of Examples 13-15, and further including one or more microlenses to couple light between the plurality of LEDs and the one or more optical fiber cores.

Example 17 includes the subject matter of any of Examples 13-16, and wherein the plurality of LEDs comprise gallium and nitrogen.

Example 18 includes the subject matter of any of Examples 13-17, and wherein the LED assembly further comprises a plurality of photodiodes.

Example 19 includes the subject matter of any of Examples 13-18, and further including a second one or more integrated circuit dies different from the one or more integrated circuit dies; a second IHS mounted on the substrate, the IHS thermally coupled to the second one or more integrated circuit dies; a second LED assembly, wherein the second LED assembly comprises a plurality of LEDs and a plurality of photodiodes, wherein the second LED assembly is mounted on the IHS; and an optical cable that optically couples the LED assembly and the second LED assembly.

Example 20 includes the subject matter of any of Examples 13-19, and wherein the second one or more integrated circuit dies are mounted on the substrate.

Example 21 includes the subject matter of any of Examples 13-20, and further including a second substrate different from the substrate, wherein the second one or more integrated circuit dies are mounted on the second substrate.

Example 22 includes the subject matter of any of Examples 13-21, and wherein a plurality of transistors are defined at a front end-of-line (FEOL) portion of the one or more integrated circuit dies, wherein the LED assembly is mounted on a back side of one of the one or more integrated circuit dies, wherein a plurality of through-silicon vias are defined in the one of the one or more integrated circuit dies, wherein the plurality of through-silicon vias connect the plurality of transistors to the LED assembly.

Example 23 includes the subject matter of any of Examples 13-22, and wherein the plurality of transistors are to modulate an amplitude of the plurality of LEDs using the plurality of through-silicon vias as a rate of at least one gigahertz.

Example 24 includes the subject matter of any of Examples 13-23, and wherein the plurality of transistors are to modulate an amplitude of the plurality of LEDs using the plurality of through-silicon vias as a rate of at least five gigahertz.

Example 25 includes the subject matter of any of Examples 13-24, and wherein the plurality of LEDs is a plurality of micro-LEDs.

Example 26 includes an apparatus comprising a substrate; an integrated circuit die mounted on the substrate; and means for converting electrical signals from the integrated circuit die to optical signals, wherein the means for converting electrical signals from the integrated circuit die to optical signals is positioned above the integrated circuit die and the substrate.

Example 27 includes the subject matter of Example 26, and wherein the means for converting electrical signals is mounted on the integrated circuit die.

Example 28 includes the subject matter of any of Examples 26 and 27, and further including an integrated heat spreader (IHS) mounted on the substrate, the IHS thermally coupled to the integrated circuit die, wherein the means for converting electrical signals is mounted on the IHS.

Example 29 includes the subject matter of any of Examples 26-28, and further including an optical receptacle mounted on the integrated circuit die, wherein the optical receptacle is to align an optical plug to couple light from the means for converting electrical signals.

Example 30 includes the subject matter of any of Examples 26-29, and further including the optical plug, wherein the optical plug is mated with the optical receptacle; and one or more optical fiber cores, wherein the one or more optical fiber cores terminate at the optical plug, wherein individual optical fiber cores of the one or more optical fiber cores are aligned to a corresponding micro-LED of the means for converting electrical signals.

Example 31 includes the subject matter of any of Examples 26-30, and further including one or more microlenses to couple light between the means for converting electrical signals and the one or more optical fiber cores.

Example 32 includes the subject matter of any of Examples 26-31, and wherein the means for converting electrical signals comprise gallium and nitrogen.

Example 33 includes the subject matter of any of Examples 26-32, and wherein the means for converting electrical signals further comprises one or more photodiodes.

Example 34 includes the subject matter of any of Examples 26-33, and further including a second integrated circuit die different from the integrated circuit die; a second means for converting electrical signals from the second integrated circuit die to optical signals, wherein the second means for converting electrical signals comprises one or more micro-LEDs and one or more photodiodes, wherein the second means for converting electrical signals is mounted on the second integrated circuit die; and an optical cable that optically couples the means for converting electrical signals and the second means for converting electrical signals.

Example 35 includes the subject matter of any of Examples 26-34, and wherein the second integrated circuit die is mounted on the substrate.

Example 36 includes the subject matter of any of Examples 26-35, and further including a second substrate different from the substrate, wherein the second integrated circuit die is mounted on the second substrate.

Example 37 includes the subject matter of any of Examples 26-36, and wherein a plurality of transistors are defined at a front end-of-line (FEOL) portion of the integrated circuit die, wherein the means for converting electrical signals is mounted on a back side of the integrated circuit die, wherein a plurality of through-silicon vias are defined in the integrated circuit die, wherein the plurality of through-silicon vias connect the plurality of transistors to the means for converting electrical signals.

Example 38 includes the subject matter of any of Examples 26-37, and wherein the plurality of transistors are to modulate an amplitude of one or more micro-LEDs of the means for converting electrical signals using the plurality of through-silicon vias as a rate of at least one gigahertz.

Example 39 includes the subject matter of any of Examples 26-38, and wherein the plurality of transistors are to modulate an amplitude of one or more micro-LEDs of the means for converting electrical signals using the plurality of through-silicon vias as a rate of at least five gigahertz.

1. An apparatus comprising:
an integrated circuit die; and
a micro-light-emitting diode (micro-LED) assembly comprising one or more micro-LEDs; wherein the micro-LED assembly is mounted on the integrated circuit die.

2. The apparatus of claim 1, further comprising:
an optical receptacle mounted on the integrated circuit die, wherein the optical receptacle is to align an optical plug to couple light from the micro-LED assembly.

3. The apparatus of claim 2, further comprising:
the optical plug, wherein the optical plug is mated with the optical receptacle; and
one or more optical fiber cores, wherein the one or more optical fiber cores terminate at the optical plug, wherein individual optical fiber cores of the one or more optical fiber cores are aligned to a corresponding micro-LED of the micro-LED assembly.

4. The apparatus of claim 3, further comprising one or more microlenses to couple light between the one or more micro-LEDs and the one or more optical fiber cores.

5. The apparatus of claim 1, wherein the one or more micro-LEDs comprise gallium and nitrogen.

6. The apparatus of claim 1, wherein the micro-LED assembly further comprises one or more photodiodes.

7. The apparatus of claim 6, further comprising:
a second integrated circuit die different from the integrated circuit die;
a second micro-LED assembly, wherein the second micro-LED assembly comprises one or more micro-LEDs and one or more photodiodes, wherein the second micro-LED assembly is mounted on the second integrated circuit die; and
an optical cable that optically couples the micro-LED assembly and the second micro-LED assembly.

8. The apparatus of claim 7, further comprising a circuit board, wherein the integrated circuit die is mounted on the circuit board, wherein the second integrated circuit die is mounted on the circuit board.

9. The apparatus of claim 7, further comprising a first circuit board and a second circuit board different from the first circuit board, wherein the integrated circuit die is mounted on the first circuit board, wherein the second integrated circuit die is mounted on the second circuit board.

10. The apparatus of claim 1, wherein a plurality of transistors are defined at a front end-of-line (FEOL) portion of the integrated circuit die, wherein the micro-LED assembly is mounted on a back side of the integrated circuit die, wherein a plurality of through-silicon vias are defined in the integrated circuit die, wherein the plurality of through-silicon vias connect the plurality of transistors to the micro-LED assembly.

11. The apparatus of claim 10, wherein the plurality of transistors are to modulate an amplitude of the one or more micro-LEDs using the plurality of through-silicon vias as a rate of at least one gigahertz.

12. The apparatus of claim 10, wherein the plurality of transistors are to modulate an amplitude of the one or more micro-LEDs using the plurality of through-silicon vias as a rate of at least five gigahertz.

13. An apparatus comprising:
a substrate;
one or more integrated circuit dies mounted on the substrate;
an integrated heat spreader (IHS) mounted on the substrate, the IHS thermally coupled to the one or more integrated circuit dies; and
a light-emitting diode (LED) assembly comprising a plurality of LEDs; wherein the LED assembly is mounted on the IHS.

14. The apparatus of claim 13, further comprising:
an optical receptacle mounted on the IHS, wherein the optical receptacle is to align an optical plug to couple light from the LED assembly.

15. The apparatus of claim 14, further comprising:
the optical plug, wherein the optical plug is mated with the optical receptacle; and
one or more optical fiber cores, wherein the one or more optical fiber cores terminate at the optical plug, wherein individual optical fiber cores of the one or more optical fiber cores are aligned to a corresponding LED of the LED assembly.

16. The apparatus of claim 15, further comprising one or more microlenses to couple light between the plurality of LEDs and the one or more optical fiber cores.

17. The apparatus of claim 13, wherein a plurality of transistors are defined at a front end-of-line (FEOL) portion of the one or more integrated circuit dies, wherein the LED assembly is mounted on a back side of one of the one or more integrated circuit dies, wherein a plurality of through-silicon vias are defined in the one of the one or more integrated circuit dies, wherein the plurality of through-silicon vias connect the plurality of transistors to the LED assembly.

18. An apparatus comprising:
a substrate;
an integrated circuit die mounted on the substrate; and
means for converting electrical signals from the integrated circuit die to optical signals, wherein the means for converting electrical signals from the integrated circuit die to optical signals is positioned above the integrated circuit die and the substrate.

19. The apparatus of claim 18, wherein the means for converting electrical signals is mounted on the integrated circuit die.

20. The apparatus of claim 18, further comprising an integrated heat spreader (IHS) mounted on the substrate, the IHS thermally coupled to the integrated circuit die,
wherein the means for converting electrical signals is mounted on the IHS.
